(19) United States
(12) Patent Application Publication
(10) Pub. No.: US 2004/0257251 A1
(43) Pub. Date: Dec. 23, 2004

(54) Digital voltage/analog current converting circuit of electron luminescent panel

(76) Inventor: Wei-Chieh Hsueh, Tainan (TW)

Correspondence Address: MADSON & METCALF, GATEWAY TOWER WEST, SUITE 900, 15 WEST SOUTH TEMPLE, SALT LAKE CITY, UT, 84101

(21) Appl. No.: 10/862,015

(22) Filed: Jun. 4, 2004

(30) Foreign Application Priority Data
Jun. 6, 2003 (TW) 092115383

(51) Int. Cl. H03M 1/00

(52) U.S. Cl. 341/136

(57) ABSTRACT

A digital voltage/analog current converting circuit includes a plurality of controllable current paths and a driving current output terminal. The driving current output terminal is in communication with the plurality of controllable current paths. At least one of the controllable current paths includes a driving current output path and a bypass path for selectively flowing therethrough a current in response to a control signal, and the current flowing through the driving current output path is outputted to the driving current output terminal.

### FIELD OF THE INVENTION

The present invention relates to a digital voltage/analog current converting circuit, and more particularly to a digital voltage/analog current converting circuit of an electron luminescent panel.

### BACKGROUND OF THE INVENTION

Recently, the OLEDs can be used as pixel units of an active matrix electron luminescent display, and thus the OLED panel is expected to substitute for the LCD in the near future.

FIG. 1 illustrates a conventional driving circuit for driving an OLED pixel. The pixel unit comprises an organic light-emitting diode OLED, four transistors t1˜t4 and a capacitor Cs (so-called as 4T1C). The gate electrode of the transistor t1 is coupled to a first scan line 3, and the other two electrodes of the transistor t1 are coupled to a data line 5 and the drain electrode of the transistor t3, respectively. The gate electrode of the transistor t2 is coupled to the first scan line 3, and the other two electrodes of the transistor t2 are coupled to the data line 5 and the gate electrode of the transistor t3, respectively. The source and drain electrodes of the transistor t3 are coupled to a source voltage Vdd and the drain electrode of the transistor t4, respectively. The gate and drain electrodes of the transistor t4 are coupled to a second scan line 4 and the P electrode of the organic light-emitting diode OLED, respectively. The N electrode of the organic light-emitting diode OLED is coupled to a ground GND. The capacitor Cs is coupled between the source electrode and gate electrode of the transistor t3.

The circuit of FIG. 1 can be operated in either a memorizing or an emission state, which are controlled by the first scan line 3 and the second scan line 4, respectively. The first scan line 3 and the second scan line 4 use the same clock signal. When the clock signal is at a high level, the first scan line 3 operates and thus the transistors t1 and t2 are switched on. Whereas, when the clock signal is at a low level, the transistor t4 is switched on.

During the memorizing state, the first scan line 3 works to switch on the transistors t1 and t2, the transistor t4 is switched off. At this time, a current from the source voltage Vdd will charge the capacitor Cs. Then, the capacitor Cs biases the transistor t3 to result in a driving current Id1 passing through the transistors t3 and t1 to the data line 5. Meanwhile, no driving current passes through the transistor t4.

During the emission state, the first scan line 3 suspends operation such that the transistors t 1 and t2 are closed, and the second scan line 4 works to switch on the transistor t4. Therefore, the driving current Id1 is zero. At this time, the voltage applied to the capacitor Cs will bias the transistor t3 to result in a driving current Id2 passing through the organic light-emitting diode OLED. The organic light-emitting diode OLED emits light accordingly.

The brightness of the light emitted from the organic light-emitting diode OLED is dependent on the driving Id2 passing through the organic light-emitting diode OLED. On the other hand, the magnitude of the driving current Id2 is determined according to the voltage applied to the capacitor Cs. The voltage applied to the capacitor Cs is determined according to driving current Id1 passing to the data line 5. Thus, the OLED panel further comprises a digital voltage/analog current converting circuit for a purpose of providing various intensities of the driving current Id1 to charge the capacitor Cs. Such digital voltage/analog current converting circuit can be directly formed on the OLED panel or an external chip.

FIG. 2 is a schematic circuit diagram illustrating a conventional 6-bit digital voltage/analog current converting circuit. The digital voltage/analog current converting circuit comprises a first current mirror 10 and a second current mirror 20. The first current mirror 10 comprises a first reference current path 110 and three controllable current paths 120, 130 and 140. In the reference current path 110 there are a PMOS transistor m1 and an NMOS transistor m2 connected in series. For each of the transistors m1 and m2, the ratio of the channel width to the channel length is indicated as W/L. The source electrode of the PMOS transistor m1 is coupled to the source voltage Vdd. The gate and drain electrodes of the PMOS transistor m1 are coupled with each other. The drain and source electrodes of the NMOS transistor m2 are coupled to the drain electrode of the PMOS transistor m1 and the ground GND, respectively. The gate electrode of the NMOS transistor m2 is coupled to a first bias voltage Vbias1. In the first controllable current path 120 there are a PMOS transistor m3 and an NMOS transistor m4 connected in series. For each of the transistors m3 and m4, the ratio of the channel width to the channel length is also indicated as W/L. The source and gate electrodes of the PMOS transistor m3 are coupled to the source voltage Vdd and the gate electrode of the PMOS transistor m1, respectively. The drain and source electrodes of the NMOS transistor m4 are coupled to the drain electrode of the PMOS transistor m3 and a driving current output terminal, respectively. The gate electrode of the NMOS transistor m4 is coupled to a control terminal D0. In the second controllable current path 130 there are a PMOS transistor m5 and an NMOS transistor m6 connected in series. For each of the transistors m5 and m6, the ratio of the channel width to the channel length is 2W/L. The source and gate electrodes of the PMOS transistor m5 are coupled to the source voltage Vdd and the gate electrode of the PMOS transistor m1, respectively. The drain and source electrodes of the NMOS transistor m6 are coupled to the drain electrode of the PMOS transistor m5 and a driving current output terminal, respectively. The gate electrode of the NMOS transistor m6 is coupled to a control terminal D1. In the third controllable current path 140 there are a PMOS transistor m7 and an NMOS transistor m8 connected in series. For each of the transistors m7 and m8, the ratio of the channel width to the channel length is 4W/L. The source and gate electrodes of the PMOS transistor m7 are coupled to the source voltage Vdd and the gate electrode of the PMOS transistor m1, respectively. The drain and source electrodes of the NMOS transistor m8 are coupled to the drain electrode of the PMOS transistor m7 and a driving current output terminal, respectively. The gate electrode of the NMOS transistor m8 is coupled to a control terminal D2.

Since these PMOS transistors m1, m3, m5 and m7 have the common gate voltage, the currents passing through the first reference current path 110 and the controllable current paths 120, 130 and 140, i.e. Iref1, I0, I1 and I2, can be determined depending on the width-to-length ratio thereof, which is in a ratio of 1:1:2:4. Therefore, when the first reference current Iref1 is generated in response to the first bias voltage Vbias1, the current passing through the first controllable current path 120 is equal to Iref1, i.e. I0=Iref1. The current passing through the second controllable current path 130 is two times Iref1, i.e. I1=2×Iref1. Furthermore, the current passing through the third controllable current path 140 is four times Iref1, i.e. I1=4×Iref1. In other words, the relation between these currents can be indicated as I2=2×I1=4×I0=4×Iref1.

The circuit configuration of the second current mirror 20 is similar to that of the first current mirror 10. The second current mirror 20 comprises a second reference current path 210 and three controllable current paths 220, 230 and 240. In the reference current path 210 there are a PMOS transistor m9 and an NMOS transistor m10 connected in series. For each of the transistors m9 and m10, the ratio of the channel width to the channel length is indicated as W/L. The first controllable current path 220 comprises a PMOS transistor m11 and an NMOS transistor m12 connected in series. For each of the transistors m11 and m12, the ratio of the channel width to the channel length is also indicated as W/L. In the second controllable current path 230 there are a PMOS transistor m13 and an NMOS transistor m14 connected in series. For each of the transistors m13 and m14, the ratio of the channel width to the channel length is 2W/L. In the third controllable current path 240 there are a PMOS transistor m15 and an NMOS transistor m16 connected in series. For each of the transistors m15 and m16, the ratio of the channel width to the channel length is 4W/L. The gate electrodes of the NMOS transistors m10, m12, m14 and m16 are coupled to a second bias voltage Vbias2 and control terminals D3˜D5, respectively.

Likewise, the current passing through the second reference current path 210 and the controllable current paths 220, 230 and 240, i.e. Iref2, 13, 14 and 15 can be indicated as I5=2×I4=4×I3=4×Iref2. Typically, the second reference current Iref2 is eight times the first reference current Iref1. Thus, the following relations between these currents can be deduced: I0=Iref1, I1=2×Iref1, I2=4×Iref1, I3=8×Iref1, I4=16×Iref1 and I5=32×Iref1.

By means of the above 6-bit digital voltage/analog current converting circuit, a variable driving current Idrv can be obtained in response to the activation of the control terminals D0˜D5. For example, when the control terminals D0, D2 and D4 are switched on, i.e. the gate electrodes of the NMOS transistors m4, m8 and m14 are in enabling states, the driving current Idrv corresponds to 21×Iref1, i.e. (1+4+16)×Iref1. In response to the enabling or disabling states of the control terminals D0˜D5, the driving currents Idrv being 0˜63 times of Iref1 are outputted accordingly. When the control terminals D0˜D5 are successively switched into enabling states, the distribution of the driving current Idrv is as shown in FIG. 3. Since the electron-hole pairs in the transistor channels are redistributed when the signals inputting to the control terminals are changed, an instantaneous spike of the driving current Idrv may be rendered. The spike might cause malfunction of the converting circuit and even the burnout of the transistors.

### SUMMARY OF THE INVENTION

It is an object of the present invention to provide a digital voltage/analog current converting circuit for use in an electroluminescent display panel, in which the generated spike is largely reduced so as to prevent malfunction of the converting circuit and the burnout of the transistors.

In accordance with a first aspect of the present invention, a digital voltage/analog current converting circuit is provided. The circuit comprises a plurality of controllable current paths and a driving current output terminal. The driving current output terminal is in communication with the plurality of controllable current paths. At least one of the controllable current paths comprises a driving current output path and a bypass path for selectively flowing therethrough a current in response to a control signal, and the current flowing through the driving current output path to the driving current output terminal.

In one embodiment, intensities of the currents respectively flowing through the plurality of controllable current paths to be outputted to the driving current output terminal are proportional to one another.

In one embodiment, each of the plurality of controllable current paths is provided with a first, a second, and a third transistor. The first transistor has a source electrode and a gate electrode coupled to a source voltage and a first bias voltage, respectively. The second transistor has a source, a gate, and a drain electrode coupled to the drain electrode of the first transistor, the control signal and a ground, respectively. The third transistor has a source, a gate, and a drain electrode coupled to the drain electrode of the first transistor, a second bias voltage and the driving current output terminal, respectively. Specifically, the first, the second, and the third transistors have respective channels of the same width-to-length ratio.

In accordance with a second aspect of the present invention, there is provided a digital voltage/analog current converting circuit. The circuit comprises a plurality of controllable current paths and a driving current input terminal. The driving current input terminal is in communication with the plurality of controllable current paths. At least one of the controllable current paths is provided with a driving current input path and a source voltage supply path for selectively flowing therethrough a current in response to a control signal, and the current flowing through the driving current input path is inputted from the driving current input terminal.

In one embodiment, intensities of the currents respectively flowing through the plurality of controllable current paths to be inputted from the driving current input terminal are proportional to one another.

In one embodiment, each of the plurality of controllable current paths is provided with a first, a second, and a third transistor. The first transistor has a source electrode and a gate electrode coupled to a ground and a first bias voltage, respectively. The second transistor has a source, a gate, and a drain electrode coupled to the drain electrode of the first transistor, the control signal and a source voltage, respectively. The third transistor has a source, a gate, and a drain electrode coupled to the drain electrode of the first transistor, a second bias voltage, and the driving current input terminal, respectively. Specifically, the first, the second, and the third transistors have respective channels of the same width-to-length ratio.

In accordance with a third aspect of the present invention, there is provided a digital voltage/analog current converting circuit. The circuit comprises a plurality of controllable current paths and a driving current output terminal. The plurality of controllable current paths are selectively conducted/closed in response to a control signal. The driving current output terminal is in communication with the plurality of controllable current paths for outputting therefrom current flowing through the conducted controllable current paths. At least one of the controllable current paths is provided with a first transistor electrically connected to the driving current output terminal in series, and the gate electrode of the first transistor is coupled to a specified voltage.

In one embodiment, each of the plurality of controllable current paths is further provided with a second and a third transistor. The second transistor has a source and a gate electrode coupled to a source voltage and a bias voltage, respectively. The third transistor has a source and a gate electrode coupled to the drain electrode of the second transistor and the control signal, respectively. The first transistor is coupled between the drain electrode of the third transistor and the driving current output terminal, and the first, the second and the third transistors have respective channels of the same width-to-length ratio.

In accordance with a fourth aspect of the present invention, there is provided a digital voltage/analog current converting circuit. The circuit comprises a plurality of controllable current paths and a driving current input terminal. The plurality of controllable current paths are selectively conducted/closed in response to a control signal. The driving current input terminal is in communication with the plurality of controllable current paths for inputting therefrom current flowing through the conducted controllable current paths. At least one of the controllable current paths is provided with a first transistor electrically connected to the driving current input terminal in series, and the gate electrode of the first transistor is coupled to a specified voltage.

In one embodiment, each of the plurality of controllable current paths is further provided with a second and a third transistor. The second transistor has a source and a gate electrode coupled to a ground and a bias voltage, respectively. The third transistor has a source and a gate electrode coupled to the drain electrode of the second transistor and the control signal, respectively. The first transistor is coupled between the drain electrode of the third transistor and the driving current input terminal, and the first, the second and the third transistors have respective channels of the same width-to-length ratio.

The above and other objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic circuit diagram illustrating a conventional pixel driving circuit of an OLED panel;

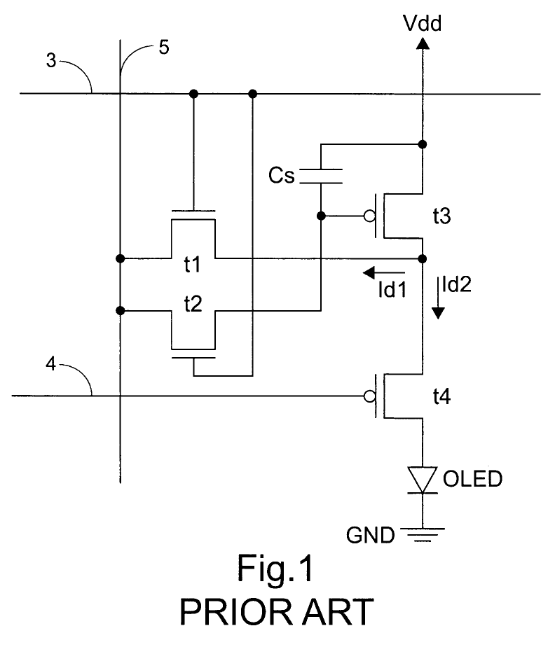

FIG. 2 is a schematic circuit diagram illustrating a conventional 6-bit digital voltage/analog current converting circuit;

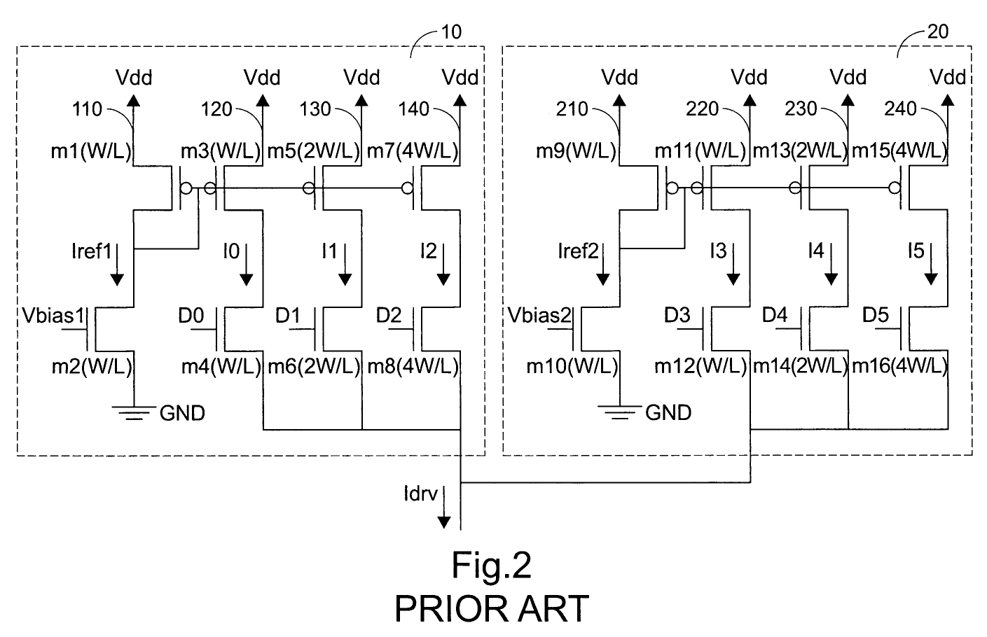

FIG. 3 is a current variation diagram of the 6-bit digital voltage/analog current converting circuit for outputting different driving currents;

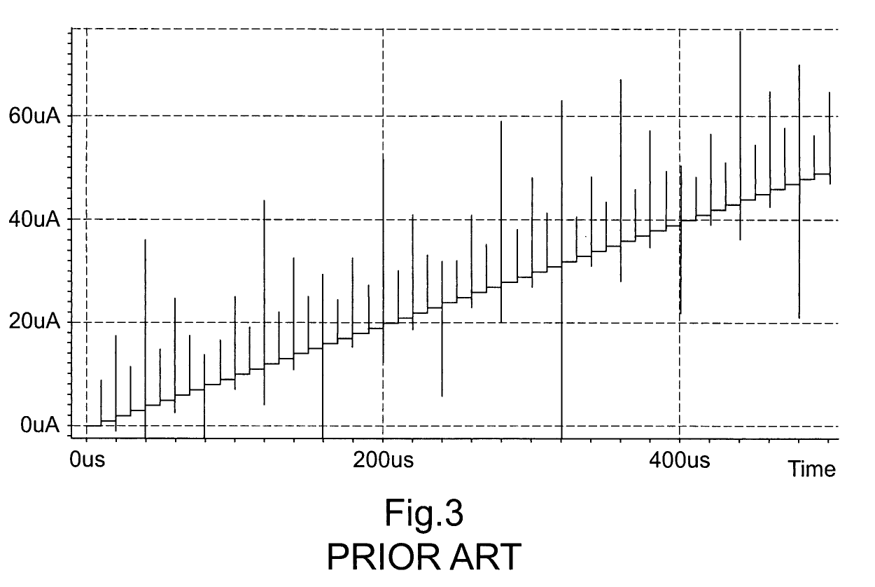

FIG. 4 is a schematic circuit diagram illustrating a 6-bit digital voltage/analog current converting circuit according to first embodiment of the present invention;

FIG. 5 is a current variation diagram of the 6-bit digital voltage/analog current converting circuit of FIG. 4 for outputting different driving currents;

FIG. 6 is a schematic circuit diagram illustrating a 6-bit digital voltage/analog current converting circuit according to second embodiment of the present invention;

FIG. 7 is a current variation diagram of the 6-bit digital voltage/analog current converting circuit of FIG. 6 for outputting different driving currents;

FIG. 8 is a schematic circuit diagram illustrating a controllable current path applied to a digital voltage/analog current converting circuit of the present invention; and

FIG. 9 is a schematic circuit diagram illustrating another controllable current path applied to a digital voltage/analog current converting circuit of the present invention.

### DETAILED DESCRIPTION OF THE PREFERRED EMBODIMENT

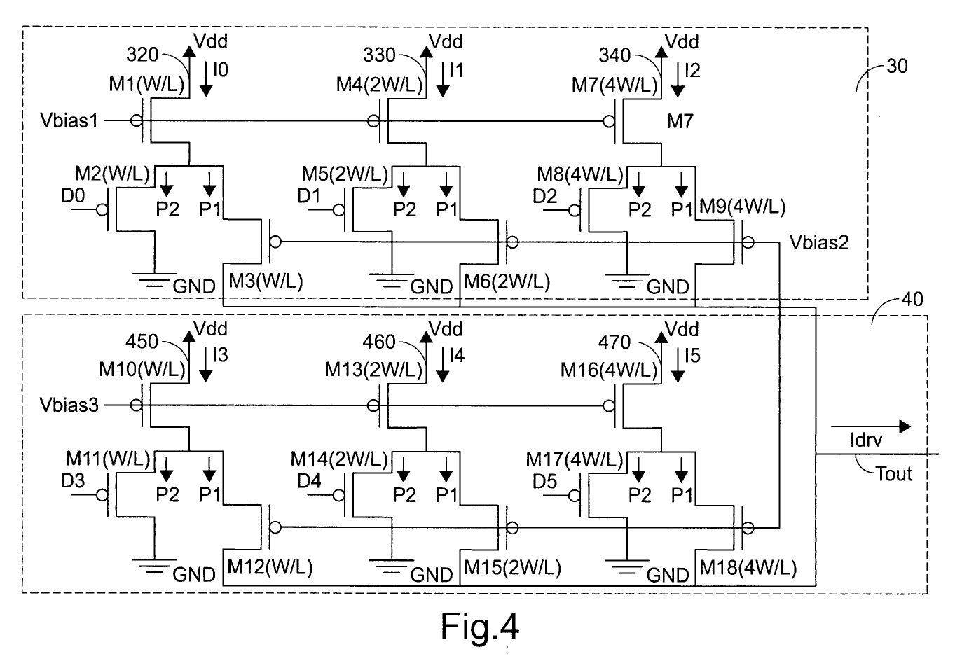

FIG. 4 is a schematic circuit diagram illustrating a 6-bit digital voltage/analog current converting circuit according to a first embodiment of the present invention. The digital voltage/analog current converting circuit comprises two driving circuits 30 and 40 with similar circuit configuration. The driving circuit 30 comprises three controllable current paths 320, 330, and 340. The controllable current path 320 is provided with three transistors M1˜M3. For each of the transistors M1˜M3, the ratio of the channel width to the channel length is indicated as W/L. The source and the gate electrodes of the transistor M1 are coupled to a source voltage Vdd and a first bias voltage Vbias1, respectively. The gate and the drain electrodes of the transistor M2 are coupled to a control terminal D0 and a ground GND, respectively. The source, the gate and the drain electrodes of the transistor M3 are coupled to the drain electrode of the transistor M1, a second bias voltage Vbias2 and a driving current output terminal Tout, respectively.

The controllable current path 330 has a circuit configuration similar to that of the controllable current path 320 and is provided with three transistors M4˜M6. For each of the transistors M4˜M6, the ratio of the channel width to the channel length is 2W/L. Likewise, the controllable current path 340 has a circuit configuration similar to that of the controllable current path 320 and is provided with three transistors M7˜M9. For each of the transistors M7˜M9, the ratio of the channel width to the channel length is 4W/L.

Since these transistors M1, M4, and M7 have the common gate voltage, the current passing through the controllable current paths 320, 330 and 340, i.e. I0, I1, and I2, can be determined depending on the width-to-length ratio thereof, which is in a ratio of 1:2:4. Therefore, in response to the first bias voltage Vbias1, the relation between these currents can be indicated as I2=2×I1=4×I0.

The circuit configuration of the driving circuit 40 is similar to that of the driving circuit 30. The gate electrodes of the transistors M10, M13, and M16 are coupled to a third bias voltage Vbias3. The driving circuit 40 comprises three controllable current paths 450, 460, and 470. The controllable current path 450 is provided with three transistors M10˜M12. For each of the transistors M10˜M12, the ratio of the channel width to the channel length is indicated as W/L. The controllable current path 460 has a circuit configuration similar to that of the controllable current path 450 and is provided with three transistors M13˜M15. For each of the transistors M13˜M15, the ratio of the channel width to the channel length is 2W/L. Likewise, the controllable current path 470 has a circuit configuration similar to that of the controllable current path 450 and is provided with three transistors M16˜M18. For each of the transistors M16˜M18, the ratio of the channel width to the channel length is 4W/L.

Likewise, the current passing through the controllable current paths 450, 460, and 470, i.e. I3, I4, and I5 can be indicated as I5=2×I4=4×I3. Furthermore, the current 13 generated form the transistor M10 biased by the third bias voltage Vbias3 is eight times the current 10 flowing through the transistor M1, i.e. I3=8×I0. Thus, the following relations between these currents can be deduced: I1=2×I0, I2=4×I0, I3=8×I0, I4=16×I0, and I5=32×I0.

The operation principle of the above 6-bit digital voltage/analog current converting circuit will be illustrated as follows with reference to FIG. 4, and the controllable current path 320 is taken as example. When a control signal inputting into the control terminal D0 is at a high level, the transistor M2 is switched off. Thus, the current 10 will flow through the driving current output path P1 and be outputted to the driving current output terminal Tout. Whereas, when the control signal inputting into the control terminal D0 is at a low level, the transistor M2 is switched on. Thus, the current I0 will flow through the bypass path P2 and be outputted to the ground GND. In other words, in response to the control signal, the current I0 is optionally transmitted to the driving current output terminal Tout via the driving current output path P1. Likewise, in response to state changes of the control terminals D1˜D5, the currents I1˜I5 will be optionally outputted to the driving current output terminal Tout via respective driving current output paths P1.

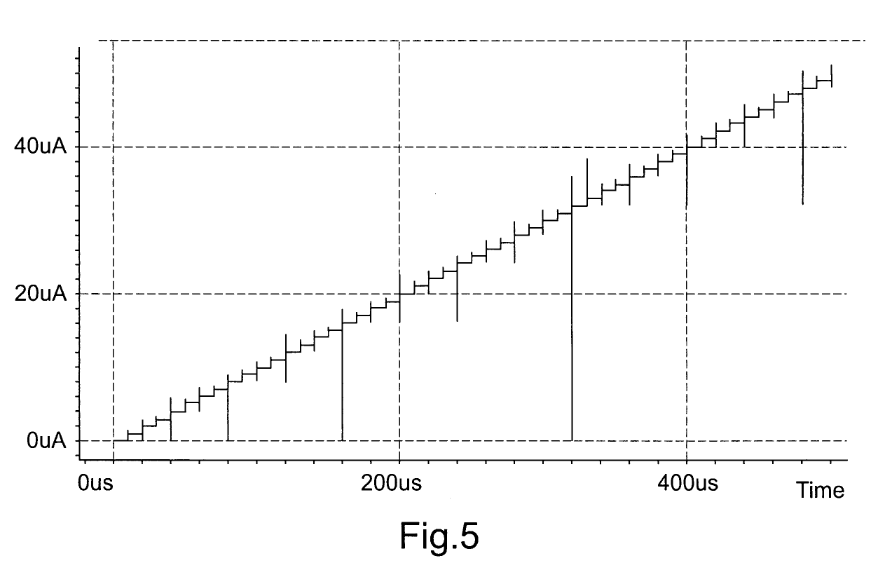

When the control terminals D0˜D5 are successively switched to disabling states, the current variation of the driving current Idrv is shown in FIG. 5. In other words, in response to the enabling or disabling states of the control terminals D0˜D5, the driving currents Idrv being 0˜63 times of I0 are outputted to the driving current output terminal Tout. Since the control terminals D0˜D5 change only corresponding current paths and not interrupt the current flow, the instantaneous spike of the driving current Idrv can be significantly reduced so as to prevent malfunction of the converting circuit and the burnout of the transistors.

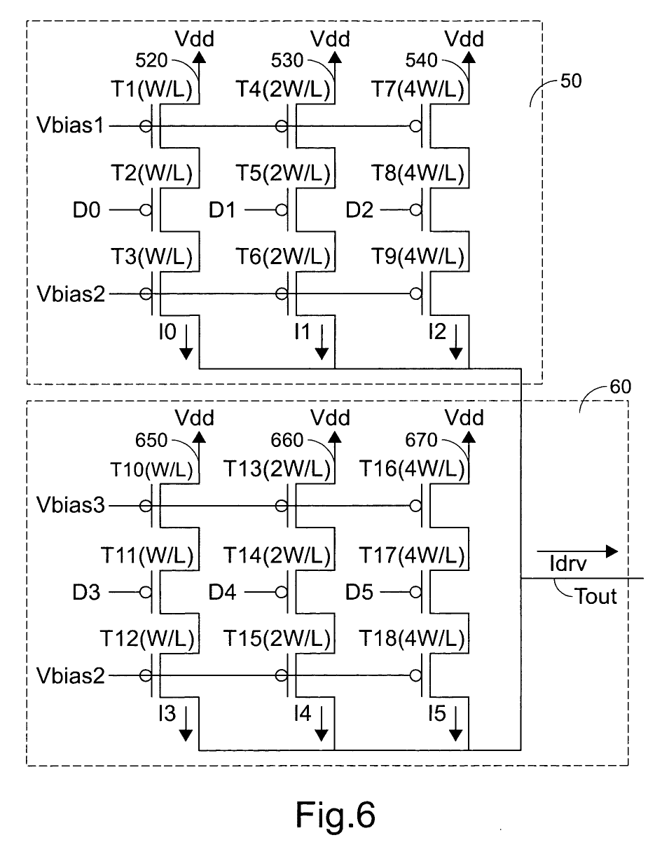

FIG. 6 is a schematic circuit diagram illustrating a 6-bit digital voltage/analog current converting circuit according to a second embodiment of the present invention. The digital voltage/analog current converting circuit comprises two driving circuits 50 and 60 with the similar circuit configuration. The driving circuit 50 comprises three controllable current paths 520, 530, and 540. The controllable current path 520 is provided with three transistors T1˜T3. For each of the transistors T1˜T3, the ratio of the channel width to the channel length is indicated as W/L. The source and the gate electrodes of the transistor T1 are coupled to a source voltage Vdd and a first bias voltage Vbias1, respectively. The source and the gate electrodes of the transistor T2 are coupled to the drain electrode of the transistor T1 and the control terminal D0, respectively. The source, the gate and the drain electrodes of the transistor T3 are coupled to the drain electrode of the transistor T2, a second bias voltage Vbias2 and a driving current output terminal Tout, respectively. The controllable current path 530 has a circuit configuration similar to that of the controllable current path 520 and is provided with three transistors T4˜T6. For each of the transistors T4˜T6, the ratio of the channel width to the channel length is 2W/L. Likewise, the controllable current path 540 has a circuit configuration similar to that of the controllable current path 520 and is provided with three transistors T7˜T9. For each of the transistors T7˜T9, the ratio of the channel width to the channel length is 4W/L.

Since these transistors T1, T4, and T7 have the common gate voltage, the currents passing through the controllable current paths 520, 530, and 540, i.e. I0, I1, and I2, can be determined depending on the width-to-length ratio thereof, which is in a ratio of 1:2:4. Therefore, in response to the first bias voltage Vbias1, the relation between these currents can be indicated as I2=2×I1=4×I0.

The circuit configuration of the driving circuit 60 is similar to that of the driving circuit 50. The gate electrodes of the transistors T10, T13, and T16 are coupled to a third bias voltage Vbias3. The driving circuit 60 comprises three controllable current paths 650, 660, and 670. The controllable current path 650 is provided with three transistors T10˜T12. For each of the transistors T10˜T12, the ratio of the channel width to the channel length is indicated as W/L. The controllable current path 660 has a circuit configuration similar to that of the controllable current path 650 and is provided with three transistors T13˜T15. For each of the transistors T13˜T15, the ratio of the channel width to the channel length is 2W/L. Likewise, the controllable current path 670 has a circuit configuration similar to that of the controllable current path 650 and is provided with three transistors T16˜T18. For each of the transistors T16˜T18, the ratio of the channel width to the channel length is 4W/L.

Likewise, the currents passing through the controllable current paths 620, 630, and 640, i.e. I3, I4, and I5 can be indicated as I5=2×I4=4×I3. Furthermore, the current 13 generated form the transistor T10 biased by the third bias voltage Vbias3 is eight times the current 10 flowing through the transistor T1, i.e. I3=8×I0. Thus, the following relations between these currents can be deduced: I1=2×I0, I2=4×I0, I3=8×I0, I4=16×I0, and I5=32×I0.

The operation principle of the above 6-bit digital voltage/analog current converting circuit will be illustrated as follows with reference to FIG. 6, and the controllable current path 520 is taken as example. When a control signal inputting into the control terminal D0 is at a low level, the transistor T2 is switched on. Thus, the current 10 will flow through the transistors T1˜T3 and be outputted to the driving current output terminal Tout. Whereas, when the control signal inputting into the control terminal D0 is at a high level, the transistor T2 is switched off, such that the current 10 is zero. Since the transistor T3 is coupled between the transistor T2 and the driving current output terminal Tout in series, and a constant voltage, i.e. the second bias voltage Vbias2, is coupled to the gate electrode of the transistor T3, the electron-hole pairs in the channels of the transistor T3 will be redistributed quickly when the control signals inputting to the control terminals are changed. Therefore, the instantaneous spike of the driving current Idrv can be significantly reduced.

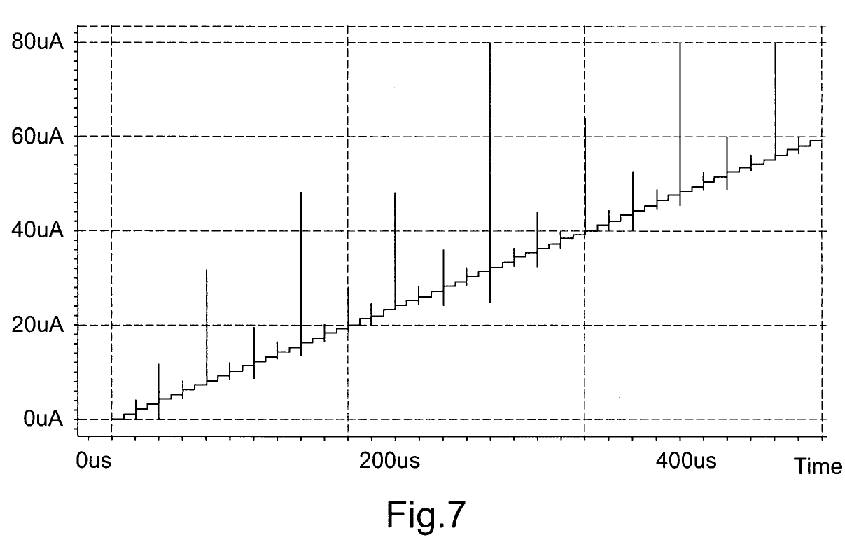

When the control terminals D0˜D5 are successively switched into enabling states, the variation of the driving current Idrv is as shown in FIG. 7. In other words, in response to the enabling or disabling states of the control terminals D0˜D5, the driving currents Idrv being 0˜63 times of I0 are outputted to the driving current output terminal Tout. Since the instantaneous spike of the driving current Idrv is significantly reduced, the malfunction of the converting circuit and the burnout of the transistors are minimized.

The above embodiments are illustrated by arranging the digital voltage/analog current converting circuit in an upstream or downstream of a pixel driving circuit to provide driving current to the pixel driving circuit.

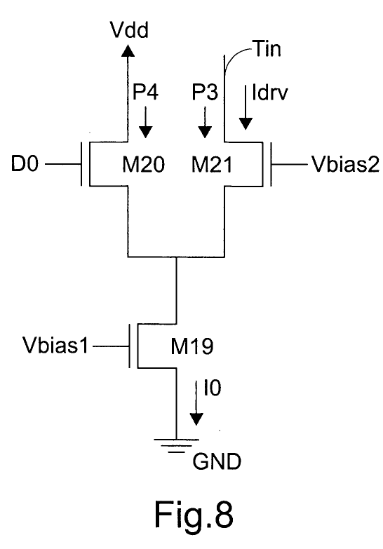

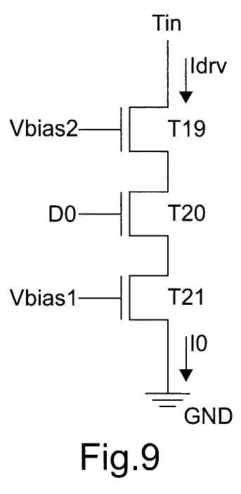

FIGS. 8 and 9 are schematic circuit diagrams illustrating a controllable current path applied to a digital voltage/analog current converting circuit of two further embodiments of the present invention. Each of the digital voltage/analog current converting circuit also comprises a plurality of controllable current paths having similar circuit configuration. For neat drawings, however, only one controllable current path is shown.

The controllable current path of FIG. 8 is provided with three transistors M19·M21. The drain and the gate electrodes of the transistor M19 are coupled to a ground GND and a first bias voltage Vbias1, respectively. The source, the gate and the drain electrodes of the transistor M20 are coupled to the drain electrode of the transistor M19, a control terminal D0, and a source voltage Vdd, respectively. The source, the gate and the drain electrodes of the transistor M21 are coupled to the drain electrode of the transistor M19, a second bias voltage Vbias2, and a driving current input terminal Tin, respectively. In response to the level of the control signal inputting to the control terminal D0, the current 10 will selectively flow through the driving current input path P3 or the source voltage supply path P4. Likewise, since the variation of the control terminal D0 results in the change between current paths P3 and P4 only instead of interrupting the current flow, the instantaneous spike of the driving current Idrv may be largely reduced so as to prevent malfunction of the converting circuit and the burnout of the transistors. According to the present invention, an advantageous digital voltage/analog current converting circuit can be formed with a plurality of controllable current paths as shown in FIG. 8, in which each ratio of channel width to channel length is different but proportional to one another.

The controllable current path of FIG. 9 is provided with three transistors T19˜T21. The drain and the gate electrodes of the transistor T21 are coupled to a ground GND and a first bias voltage Vbias1, respectively. The source and the gate electrodes of the transistor T20 are coupled to the drain electrode of the transistor T21 and a control terminal D0, respectively. The source, the gate and the drain electrodes of the transistor T19 are coupled to the drain electrode of the transistor T20, a second bias voltage Vbias2 and a driving current input terminal Tin, respectively. Since the transistor T19 is coupled between the transistor T20 and the driving current input terminal Tin and a constant voltage, i.e. the second bias voltage Vbias2, is coupled to the gate electrode of the transistor T19, the electron-hole pairs in the channels of the transistor T19 will be redistributed quickly when the control signals input to the control terminals are changed. Therefore, the instantaneous spike of the driving current Idrv can be largely reduced. According to the present invention, an advantageous digital voltage/analog current converting circuit can be formed with a plurality of controllable current paths as shown in FIG. 9, in which each ratio of channel width to channel length is different but proportional to one another.

From the above description, it is understood that the digital voltage/analog current converting circuits according to the present invention can effectively reduce the instantaneous spike resulting from the state changes of the control signals at the control terminals.

While the invention has been described in terms of what is presently considered to be the most practical and preferred embodiments, it is to be understood that the invention is not limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A digital voltage/analog current converting circuit comprising:
a plurality of controllable current paths; and
a driving current output terminal in communication with said plurality of controllable current paths,
wherein at least one of said controllable current paths comprises a driving current output path and a bypass path for selectively flowing therethrough a current in response to a control signal, and the current flowing through said driving current output path is outputted to said driving current output terminal.

2. The converting circuit according to claim 1, wherein intensities of the currents respectively flowing through said plurality of controllable current paths to said driving current output terminal are proportional to one another.

3. The converting circuit according to claim 1, wherein each of said plurality of controllable current paths comprises:
a first transistor having a source and a gate electrodes coupled to a source voltage and a first bias voltage, respectively;
a second transistor having a source, a gate and a drain electrodes coupled to said drain electrode of said first transistor, said control signal and a ground, respectively; and
a third transistor having a source, a gate and a drain electrodes coupled to said drain electrode of said first transistor, a second bias voltage and said driving current output terminal, respectively,
wherein said first, said second and said third transistors have respective channels of the same width-to-length ratio.

4. A digital voltage/analog current converting circuit comprising:
a plurality of controllable current paths; and
a driving current input terminal in communication with said plurality of controllable current paths,
wherein at least one of said controllable current paths comprises a driving current input path and a source voltage supply path for selectively flowing therethrough a current in response to a control signal, and the current flowing through said driving current input path is inputted from said driving current input terminal.

5. The converting circuit according to claim 4, wherein intensities of the currents respectively flowing through said plurality of controllable current paths to be inputted from said driving current input terminal are proportional to one another.

6. The converting circuit according to claim 4, wherein each of said plurality of controllable current paths comprises:
a first transistor having a drain, a source coupled to a ground and a gate electrodes coupled to a first bias voltage;
a second transistor having a source, a gate and a drain electrodes coupled to said drain electrode of said first transistor, said control signal and a source voltage, respectively; and
a third transistor having a source, a gate and a drain electrodes coupled to said drain electrode of said first transistor, a second bias voltage and said driving current input terminal, respectively,
wherein said first, said second and said third transistors have respective channels of the same width-to-length ratio.

7. A digital voltage/analog current converting circuit comprising:
a plurality of controllable current paths being selectively conducted or disconducted in response to a control signal; and
a driving current output terminal in communication with said plurality of controllable current paths for outputting therefrom current flowing through said conducted controllable current paths,
wherein at least one of said controllable current paths comprises a first transistor electrically connected to said driving current output terminal in series, and the gate electrode of said first transistor is coupled to a specified voltage.

8. The converting circuit according to claim 7, wherein intensities of the currents respectively flowing through said plurality of controllable current paths to said driving current output terminal are proportional to one another.

9. The converting circuit according to claim 7, wherein each of said plurality of controllable current paths further comprises:
a second transistor having a drain, a source coupled to a source voltage and a gate electrode coupled to a bias voltage; and
a third transistor having a source and a gate electrode coupled to the drain electrode of said second transistor and said control signal, respectively,
wherein said first transistor is coupled between the drain electrode of said third transistor and said driving current output terminal, and said first, said second and said third transistors have respective channels of the same width-to-length ratio.

10. A digital voltage/analog current converting circuit comprising:
a plurality of controllable current paths being conducted or disconducted in response to a control signal; and
a driving current input terminal in communication with said plurality of controllable current paths for inputting therefrom current flowing through said conducted controllable current paths,
wherein at least one of said controllable current paths comprises a first transistor electrically connected to said driving current input terminal in series, and said first transistor has a gate electrode coupled to a specified voltage.

11. The converting circuit according to claim 10, wherein intensities of the currents respectively flowing through said plurality of controllable current paths to be inputted from said driving current input terminal are proportional to one another.

12. The converting circuit according to claim 10, wherein each of said plurality of controllable current paths further comprises:
a second transistor having a drain, a source coupled to a ground and a gate electrode coupled to a bias voltage; and
a third transistor having a source and a gate electrode coupled to the drain electrode of said second transistor and said control signal, respectively,
wherein said first transistor is coupled between the drain electrode of said third transistor and said driving current input terminal, and said first, said second and said third transistors have respective channels of the same width-to-length ratio.
